(19) United States
(12) Patent Application Publication
(10) Pub. No.: US 2026/0231539 A1
(43) Pub. Date: Aug. 6, 2026

(54) HIGH-GAIN TIME-DELAY-INTEGRATION SENSOR FOR INSPECTION TOOL

(71) Applicant: KLA Corporation, Milpitas, CA (US)

(72) Inventors: Sanghoon Bae, San Jose, CA (US); John Fielden, Los Altos, CA (US); Devis Contarato, San Carlos, CA (US); Venkatraman IYER, Saratoga, CA (US)

(21) Appl. No.: 19/465,943

(22) Filed: Jan. 30, 2026

Related U.S. Application Data
(60) Provisional application No. 63/754,535, filed on Feb. 5, 2025.

(51) Int. Cl. H10F 39/15; G01J 1/44; G01N 21/88; G01N 21/95

(52) U.S. Cl. CPC H10F 39/1538; G01J 1/44; G01N 21/8806; G01N 21/9501; G01J 2001/448

(57) ABSTRACT

An image sensor and method are disclosed. The image sensor may include a silicon layer including a light-sensitive surface and an opposing surface on an opposite side from the light-sensitive surface. A plurality of circuits may be formed on the opposing surface of the silicon layer where the plurality of circuits collectively includes an array of pixels configured to be photosensitive and a non-pixel region including a plurality of transfer gates and one or more amplifiers. An avalanche region may be defined by one or more avalanche layers, and a non-avalanche region may be defined by an absence of avalanche layers. The avalanche region may be selectively disposed overlapping in a first direction with the array of pixels. The non-avalanche region may be defined overlapping in the first direction with at least a portion of the non-pixel region.

### CROSS REFERENCE TO RELATED APPLICATIONS

The present application claims the benefit of U.S. Provisional Application Serial Number 63/754,535, filed February 5, 2025, which is incorporated herein by reference in its entirety.

### TECHNICAL FIELD

The present disclosure generally relates to image sensors and associated electronic circuits suitable for sensing radiation at visible, ultraviolet (UV), deep UV (DUV), vacuum UV (VUV), extreme UV (EUV), and X-ray wavelengths, and for sensing electrons or other charged particles, and to methods for operating such image sensors. The sensors and circuits are particularly suitable for use in charge-coupled devices (CCDs) for application in inspection and metrology systems, including those used to inspect photomasks, reticles, semiconductor wafers, substrates for supporting and/or interconnecting semiconductors, and printed circuit boards (PCBs). The sensors and circuits can also be adapted for use in image sensors fabricated using Complementary Metal Oxide-Semiconductor (CMOS) manufacturing processes.

### BACKGROUND

The semiconductor and integrated circuit industry requires a large number of fabrication processes to form various features and multiple levels of the semiconductor devices. Examples of such fabrication processes include, but are not limited to, lithography, chemical-mechanical polishing (CMP), etch, deposition, and ion implantation. These fabrication processes require inspection tools providing increasingly higher sensitivity to detect smaller defects and particles, while maintaining high throughput for a lower cost of ownership. The semiconductor industry is currently manufacturing semiconductor devices with feature dimensions around 20 nanometers (nm) and smaller. Within a few years, the industry may be manufacturing devices with feature dimensions around 5nm. Particles and defects just a few nm in size can reduce wafer yields and must be captured with high accuracy to ensure high production yield, while doing so in a time and cost-effective way. In the future, the possible transition from today's 300mm wafers to 450mm wafers may also require increased inspection speed to maintain high throughput. Thus, the semiconductor industry is driven by ever greater demand for inspection tools that can achieve high sensitivity at high speed.

An image sensor is a key component of a semiconductor inspection tool and plays a critical role in determining defect detection sensitivity and inspection speed. In order to detect small defects or particles on photomasks, reticles, and semiconductor wafers, image sensors need to have good signal-to-noise ratio (SNR). Increasing the intensity of the light used to illuminate the article being inspected can also increase the sensor signal relative to the noise. However, high power densities from the illumination are expensive to generate, can degrade the optics of the inspection system, and may damage the article being inspected. Furthermore, some defects may counterintuitively be most detectable in low light conditions (e.g., dark field conditions), such as for some types of defects using time-delay integration (TDI) sensors. Therefore, image sensors with low noise that can operate at high speed are often used.

Considering their image quality, light sensitivity, and readout noise performance, charge-coupled devices (CCDs) are widely used as image sensors for semiconductor inspection applications. CCDs are especially suited to be configured to function as a TDI sensor, due to their ability to move and integrate the signal charge, generated in the CCD sensors in response to light collected from the sample being inspected, in synchrony with the motion of the stage on which the sample is held.

Sources of noise in an image sensor include dark current within the sensor, readout noise in the sensor output signal(s), noise in the electronics that amplifies and digitizes the sensor output signal(s), and noise from external electronics, including drivers and controllers, that gets coupled into the sensor output signal.

Therefore, a need arises for an image sensor capable of detecting low light levels at high speed with high signal-to-noise ratio to overcome the above disadvantages.

### SUMMARY

An image sensor is disclosed in accordance with one or more illustrative embodiments of the present disclosure. In one illustrative embodiment, the image sensor includes a silicon layer including a light-sensitive surface and an opposing surface on an opposite side from the light-sensitive surface. In another illustrative embodiment, the image sensor includes a plurality of circuits formed on the opposing surface of the silicon layer. In another illustrative embodiment, the plurality of circuits collectively include an array of pixels configured to be photosensitive. In another illustrative embodiment, the plurality of circuits collectively include a non-pixel region including a plurality of transfer gates and one or more amplifiers. In another illustrative embodiment, the image sensor includes an avalanche region defined by one or more avalanche layers. In another illustrative embodiment, the image sensor includes a non-avalanche region defined by an absence of avalanche layers. In another illustrative embodiment, the avalanche region is selectively disposed overlapping in a first direction with the array of pixels. In another illustrative embodiment, the non-avalanche region is defined overlapping in the first direction with at least a portion of the non-pixel region.

In a further aspect, the non-avalanche region may be defined overlapping in the first direction with both the plurality of transfer gates and the one or more amplifiers.

In a further aspect, the non-avalanche region may be defined overlapping in the first direction with an entirety of both the plurality of transfer gates and the one or more amplifiers.

In a further aspect, the avalanche region may include at least a p-type doped layer and an n-type doped layer.

In a further aspect, the array of pixels may be arranged in a two-dimensional array to detect radiation.

In a further aspect, the non-pixel region may be disposed adjacent to the array of pixels. In another illustrative embodiment, the plurality of transfer gates may be configured to transfer charge from the array of pixels.

In a further aspect, the non-pixel region may further include a floating diffusion structure configured to convert charge to voltage. In another illustrative embodiment, the one or more amplifiers may be configured to amplify the voltage, wherein the voltage is a signal having a voltage level, and wherein amplifying the voltage includes at least one of increasing the voltage or increasing the current.

In a further aspect, the silicon layer may include a silicon epitaxial layer.

In a further aspect, the image sensor may be configured as a backside illuminated charge-coupled device (CCD) sensor.

In a further aspect, the image sensor may be configured as a backside illuminated complementary metal-oxide-semiconductor (CMOS) sensor.

In a further aspect, the image sensor may be configured to function as a time-delay integration (TDI) sensor.

In a further aspect, the image sensor may further include an isolation structure at least partially enclosing the non-avalanche region, and configured to at least partially electrically isolate the non-avalanche region.

In a further aspect, the isolation structure may be configured to be biased to a reference voltage.

In a further aspect, the isolation structure may include a series of electrically connected layers, including at least one n-type layer.

In a further aspect, the series of electrically connected layers may be arranged in a stack and include an N+ region, an n-well, and a deep n-well extending from the opposing surface of the silicon layer.

A system configured for inspecting or measuring a sample is disclosed. In one illustrative embodiment, the system includes an illumination sub-system configured for directing light generated by an illumination source to the sample. In another illustrative embodiment, the system includes an image sensor positioned in a path of light from the sample. In another illustrative embodiment, the image sensor includes a silicon layer including a light-sensitive surface and an opposing surface on an opposite side from the light-sensitive surface. In another illustrative embodiment, the image sensor includes a plurality of circuits formed on the opposing surface of the silicon layer. In another illustrative embodiment, the plurality of circuits collectively include an array of pixels. In another illustrative embodiment, the plurality of circuits collectively include a non-pixel region including a plurality of transfer gates and one or more amplifiers. In another illustrative embodiment, the image sensor includes an avalanche region defined by one or more avalanche layers. In another illustrative embodiment, the image sensor includes a non-avalanche region defined by an absence of avalanche layers. In another illustrative embodiment, the avalanche region is selectively disposed overlapping in a first direction with the array of pixels. In another illustrative embodiment, the non-avalanche region is defined overlapping in the first direction with at least a portion of the non-pixel region. In another illustrative embodiment, the system includes a controller configured to receive output generated by the image sensor.

In a further aspect, the system may be configured as at least one of an inspection system or a metrology system.

A method for inspecting or measuring a sample is disclosed. In one illustrative embodiment, the method includes directing and focusing light onto the sample. In another illustrative embodiment, the method includes collecting light from the sample and directing the collected light to an image sensor. In another illustrative embodiment, the image sensor includes a silicon layer including a light-sensitive surface and an opposing surface on an opposite side from the light-sensitive surface. In another illustrative embodiment, the image sensor includes a plurality of circuits formed on the opposing surface of the silicon layer. In another illustrative embodiment, the plurality of circuits collectively include an array of pixels. In another illustrative embodiment, the plurality of circuits collectively include a non-pixel region including a plurality of transfer gates and one or more amplifiers. In another illustrative embodiment, the image sensor includes an avalanche region defined by one or more avalanche layers. In another illustrative embodiment, the image sensor includes a non-avalanche region defined by an absence of avalanche layers. In another illustrative embodiment, the avalanche region is selectively disposed overlapping in a first direction with the array of pixels. In another illustrative embodiment, the non-avalanche region is defined overlapping in the first direction with at least a portion of the non-pixel region.

In a further aspect, converting a voltage output by each sensing node of the image sensor to a digital number via a readout circuit including an Analog-to-Digital Converter (ADC) may be further included.

In a further aspect, the non-avalanche region may be defined overlapping in the first direction with both the plurality of transfer gates and the one or more amplifiers.

It is to be understood that both the foregoing general description and the following detailed description are exemplary and explanatory only and are not necessarily restrictive of the invention as claimed. The accompanying drawings, which are incorporated in and constitute a part of the specification, illustrate embodiments of the invention and together with the general description, serve to explain the principles of the invention.

### BRIEF DESCRIPTION OF THE DRAWINGS

The numerous advantages of the disclosure may be better understood by those skilled in the art by reference to the accompanying figures.

FIG. 1 illustrates a schematic diagram depicting a side, cross-sectional view of an image sensor configured as a backside-illuminated avalanche time-delay-integration image sensor that includes avalanche layers fully overlapping an array of pixels, and a non-pixel region.

FIG. 2 illustrates a schematic diagram depicting a side, cross-sectional view of an image sensor configured as a backside-illuminated avalanche time-delay-integration image sensor, where the avalanche layers are selectively disposed only in line with the array of pixels, and not in a non-avalanche region that is in line with the non-pixel region, in accordance with one or more embodiments of the present disclosure.

FIG. 3 illustrates a schematic diagram depicting a side, cross-sectional view of an image sensor further including an isolation structure enclosing the non-avalanche region, in accordance with one or more embodiments of the present disclosure.

FIG. 4 illustrates a diagram of a signal chain from radiated light to an image, in accordance with one or more embodiments of the present disclosure.

FIG. 5 illustrates a schematic diagram depicting a side, cross-sectional view of a portion of an image sensor on the top and a top plan view of an architectural diagram of the image sensor on the bottom, in accordance with one or more embodiments of the present disclosure.

FIG. 6 illustrates a simplified block diagram of an optical system including one or more of the image sensors, in accordance with one or more embodiments of the present disclosure.

FIG. 7 illustrates a flow diagram depicting a method for inspecting a sample, in accordance with one or more embodiments of the present disclosure.

### DETAILED DESCRIPTION

Reference will now be made in detail to the subject matter disclosed, which is illustrated in the accompanying drawings. The present disclosure has been particularly shown and described with respect to certain embodiments and specific features thereof. The embodiments set forth herein are taken to be illustrative rather than limiting. It should be readily apparent to those of ordinary skill in the art that various changes and modifications in form and detail may be made without departing from the spirit and scope of the disclosure.

Conventional methods of triggering avalanche multiplication of electrons in semiconductor-based image sensors typically use a strong reverse bias applied through the avalanche layers which typically include one p-type layer (Pava) and one n-type layer (Nava). For example, the strong reverse bias may include a strong negative voltage applied via the Pava layer.

It is contemplated herein that such a strong reverse bias of the avalanche layers may be beneficial to the pixel array to trigger avalanche multiplication and boost the signal collected in the pixels but may cause drawbacks for the image sensor. When the strong negative voltage is under the amplifier and transfer gates, threshold voltages of the transistors and gates may be shifted because the negative voltage at the Pava layer acts as a substrate bias for the transistors of amplifiers and transfer gates. The shifted threshold voltages lead to lower and less consistent gain of the amplifiers and less stable charge transfer through the transfer gates. Another disadvantage of having the strong negative voltage at the Pava layer under the transistors and transfer gates is that it may cause devices in the amplifier and transfer gate areas to breakdown prematurely during device operation because of the corresponding strong electric field formed in the vertical/depth direction. A further disadvantage of having the avalanche layers underneath transfer gates, floating diffusion and amplifiers is that dark current and any photoelectrons generated underneath these circuits will be amplified and may degrade operation of those circuits.

Embodiments of the present disclosure are directed to an improvement in avalanche image sensors for semiconductor inspection systems to enable readout of low noise signals at high readout speed. Embodiments may implement a non-avalanche region defined by an absence of avalanche layers under the transfer gates and amplifiers. The avalanche layers may still be selectively placed in an area under the avalanche pixel array. Since there is no strong negative voltage bias under the area of amplifier and transfer gate devices, the gain of the amplifiers may be relatively higher and more consistent, and the charge transfer through the transfer gates may be more stable. Also, there would be less parasitic capacitance caused at the transfer gates. In addition, breakdown voltages of device structures including floating diffusion (FD) structures at the sensing nodes of the image sensor may be higher because there would no longer be a strong electric field in the vertical/depth direction.

Alternatively, and/or in addition, embodiments may implement an isolation structure surrounding the non-avalanche region, for further electrical isolation of the non-avalanche region.

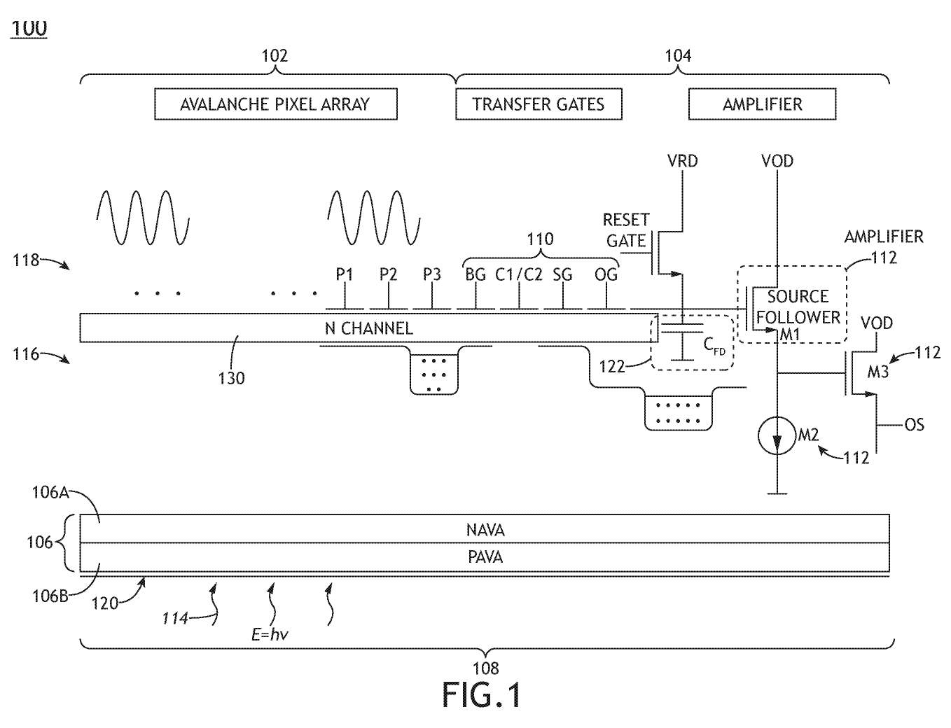

FIG. 1 illustrates a schematic diagram depicting a side, cross-sectional view of an image sensor 100 configured as a backside-illuminated avalanche time-delay-integration image sensor that includes avalanche layers 106 fully overlapping an array of pixels 102, and a non-pixel region 104. The avalanche layers 106 are continuously disposed over an entirety of the image sensor 100. Although FIG. 1 illustrates an image sensor with undesirable drawbacks, various aspects of the image sensor of FIG. 1 may still be shared and used in one or more embodiments of the present disclosure.

In embodiments, the image sensor 100 includes a silicon layer 116 that includes a light-sensitive surface 120 (e.g., backside surface) and an opposing surface 118 (e.g., frontside surface) on an opposite side from the light-sensitive surface 120.

In embodiments, the image sensor 100 includes an avalanche region 108 that includes avalanche layers 106. For example, the avalanche layers 106 may include a p-type doped layer 106B and an n-type doped layer 106A. The avalanche layers 106 may receive radiation 114 (e.g., electrons, photons/light, or the like). The avalanche region 108 defines the boundary and footprint of the avalanche layers 106. For example, the radiation 114 may include electromagnetic radiation at visible, ultraviolet (UV), deep UV (DUV), vacuum UV (VUV), extreme UV (EUV), and/or X-ray wavelengths. For instance, the image sensor 100 may be configured to detect radiation 114 at wavelengths between 1 nanometer (nm) and 800nm. As noted above, these aspects of image sensor 100 may be shared with any other image sensor herein, such as image sensor 200 described later herein.

As viewed in a first direction, the avalanche region 108 may overlap all circuits on the opposing surface 118. For example, the avalanche region 108 may overlap the array of pixels 102 and a non-pixel region 104. Overlap means to align with. For example, overlap includes being placed below/under, with none or one or more intermediate layers.

For purposes of the present disclosure, a first direction means a plan view of a plurality of circuits of the image sensor. The first direction may be referred to as a top-down view, toward a depth direction, normal to a top surface of the sample, and the like. For a wafer or chip, a first direction is facing normal to a top or bottom surface of the wafer or chip. The first direction may be orthogonal to a second and third direction along which the plurality of circuits may be disposed.

In embodiments, the non-pixel region 104 includes a plurality of transfer gates 110 (e.g., charge transfer gates), a floating diffusion structure 122, and one or more amplifiers 112 (e.g., M1, M2, M3). The one or more amplifiers 112 may be configured to amplify and/or buffer the output from a floating diffusion structure 122. For example, the one or more amplifiers 112 may include a source follower amplifier. The image sensor 100 may include an N channel region 130 near the opposing surface 118 and below the array of pixels 102 and the transfer gates 110.

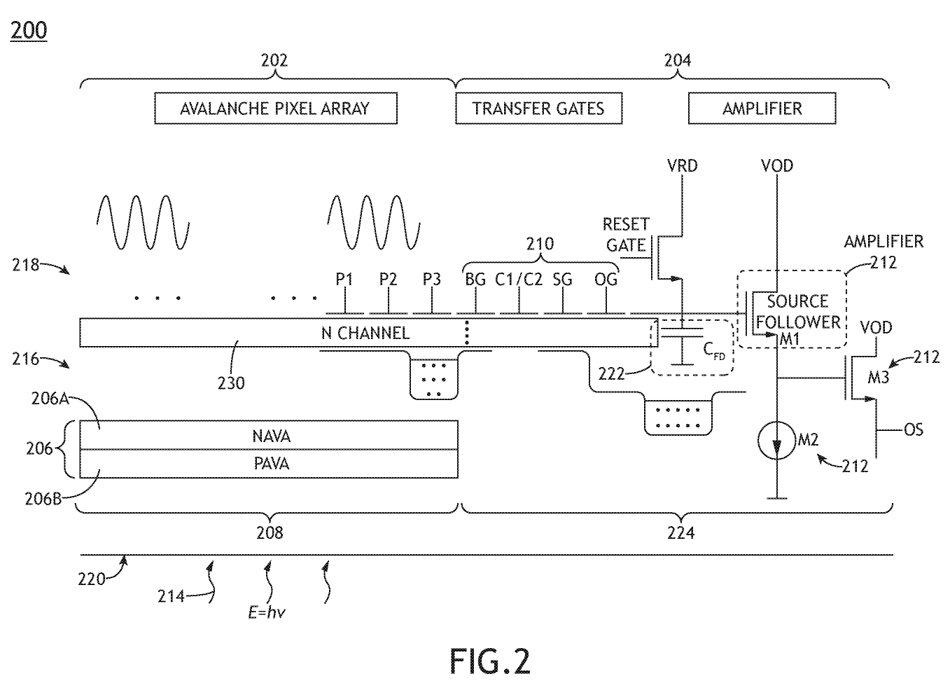

FIG. 2 illustrates a schematic diagram depicting a side, cross-sectional view of an image sensor 200 configured as a backside-illuminated avalanche time-delay-integration image sensor, where the avalanche layers 206 are selectively disposed only in line with the array of pixels 202, in accordance with one or more embodiments of the present disclosure. In embodiments, the avalanche layers 206 are not located in a non-avalanche region 224 that is in line with the non-pixel region 204.

Similar to the image sensor 100 of FIG. 1, the image sensor 200 may include a silicon layer 216. The silicon layer 216 may include a light-sensitive surface 220 and an opposing surface 218 on an opposite side from the light-sensitive surface 220. A plurality of circuits may be formed on the opposing surface 218 of the silicon layer 216. The silicon layer 216 may include a silicon epitaxial layer.

In embodiments, the image sensor 200 includes multiple functional blocks. The blocks may include an avalanche array of pixels 202 that may be fabricated with complementary metal-oxide-semiconductor (CMOS) or charge-coupled device (CCD) technology, and a non-pixel region 204. In embodiments, the array of pixels 202 are configured to be photosensitive. The array of pixels 202 may be arranged in a two-dimensional array to detect radiation 214 (e.g., incident light). In embodiments, the non-pixel region 204 includes a plurality of transfer gates 210 and one or more amplifiers 212. In embodiments, the image sensor 200 includes an N channel region 230 near the opposing surface 218 and below the array of pixels 202 and the transfer gates 210.

In embodiments, avalanche layers 206 may be located closer to opposing surface 218 than to light-sensitive surface 220. In embodiments, avalanche layers 206 may be located closer to the N channel region 230 than to the light-sensitive surface 220. The N channel region 230 may be a single continuous channel spanning the array of pixels 202 and the transfer gates 210. However, in some examples, the N channel region 230 may be split into a first N channel region below the array of pixels 202 and a second N channel region below the transfer gates 210.

The array of pixels 202 generates electrons in response to incident light. In embodiments, the number of photo-generated electrons is increased by avalanche multiplication (i.e., impact ionization) that is triggered by a high electric field bias formed in the image sensor 200 at the avalanche layers 206. Due to the avalanche multiplication, the ensuing gain (M) of charge generated per pixel 202 is higher than unity. In embodiments, the multiplied electrons are transported and summed through multiple rows of pixels 202 toward the edge of the array of pixels 202, while a sample is moving relative to the image sensor 200 field of view. This relative movement of the field of view across the sample surface allows the sample to be scanned by the image sensor 200. When the accumulated electrons reach a boundary of the array of pixels 202, the accumulated electrons are transported by the transfer gates 210. In embodiments, the transported electrons (i.e., charge) are converted to a voltage signal via floating diffusion (FD) structures 222. The voltage signal may be amplified by one or more amplifiers 212, and the amplified voltage signal may be output. The corresponding voltage signal may be read out by a readout IC (e.g., Analog-to-Digital Converter (ADC)). This process may cause the image sensor 200 to generate a relatively high-quality image compared to other techniques.

In embodiments, the non-pixel region 204 may be disposed adjacent to the array of pixels 202. The plurality of transfer gates 210 may be configured to transfer charge (i.e., charge carriers) from the array of pixels 202.

As noted, the non-pixel region 204 may further include a floating diffusion structure 222 configured to convert charge to voltage, and the one or more amplifiers 212 may be configured to amplify the voltage. In embodiments, the voltage is a term used to describe a signal having a voltage level, and amplifying the voltage includes at least one of increasing the voltage or increasing the current.

In embodiments, the image sensor 200 includes an avalanche region 208 defined by one or more avalanche layers 206 selectively disposed on the image sensor 200. For purposes of the present disclosure, "selectively disposed" means disposed in at least a portion of at least one region, but not completely disposed over an entirety of all regions of the image sensor 200. The avalanche region 208 may be selectively disposed overlapping in plain view in a first direction with the array of pixels 202. For example, the avalanche region 208 may overlap the entirety or nearly the entirety (e.g., more than 95 percent) of the array of pixels 202. In embodiments, the avalanche region 208 includes a p-type doped layer 206B which may be referred to as a Pava layer, and an n-type doped layer 206A which may be referred to as a Nava layer.

In embodiments, the avalanche layers 206 are formed using any suitable process. For example, the avalanche layers 206 may be formed by ion implantation using a patterned mask to define the lateral extent of the avalanche region 208. For example, a photoresist mask or a hard mask may be used to block ion implantation in areas corresponding to the non-avalanche region 224. For instance, the n-type doped layer 206A may be formed by implanting n-type dopants (e.g., phosphorus, arsenic, or the like) through openings in the mask, and the p-type doped layer 206B may be formed by implanting p-type dopants (e.g., boron, or the like) through openings in the mask. However, note that this is a nonlimiting example and that the avalanche layers 206 may be formed by any suitable fabrication process.

In contrast to the image sensor 100 of FIG. 1, the image sensor 200 may include a non-avalanche region 224, characterized and defined by an absence of avalanche layers 206. The non-avalanche region 224 may be defined by at least one edge of the avalanche region 208. The non-avalanche region 224 may be defined overlapping in a first direction with at least a portion of the non-pixel region 204.

Note that there may exist a transition region (not shown) between the non-avalanche region 224 and the avalanche region 208, where the transition region includes a diffused, graded doping profile. The transition region may be a byproduct of the manufacturing process, rather than a desired outcome.

The non-avalanche region 224 may cover any suitable portions of the image sensor 200. For example, the non-avalanche region 224 may partially and/or fully overlap elements. For example, the non-avalanche region 224 may partially and/or fully overlap the plurality of transfer gates 210 and the one or more amplifiers 212. For example, at least 50 percent of the non-pixel region 204 may be overlapped by the non-avalanche region 224. In another example, the non-avalanche region 224 may be defined as overlapping both the plurality of transfer gates 210 and the one or more amplifiers 212. For instance, the non-avalanche region 224 may be defined as overlapping a portion of each of the plurality of transfer gates 210 and the one or more amplifiers 212. For additional benefit, an entirety of the non-pixel region 204 may be overlapped by the non-avalanche region 224.

The image sensor 200 may be configured as a backside illuminated charge-coupled device (CCD) sensor.

The image sensor 200 may be configured as a backside illuminated complementary metal-oxide-semiconductor (CMOS) sensor.

The image sensor 200 may be configured to function as a time-delay integration (TDI) sensor.

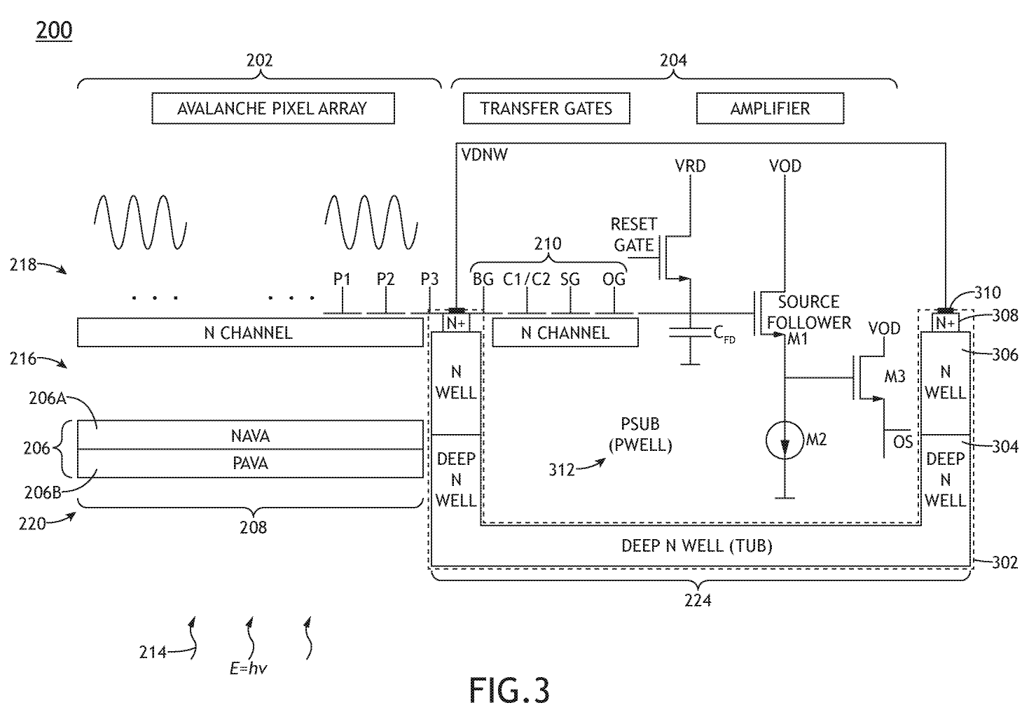

FIG. 3 illustrates a schematic diagram depicting a side, cross-sectional view of an image sensor 200 further including an isolation structure 302 enclosing the non-avalanche region 224, in accordance with one or more embodiments of the present disclosure.

The isolation structure 302 may be configured to at least partially electrically isolate the non-avalanche region 224. For example, the isolation structure 302 may extend along a perimeter of the non-avalanche region 224 to form a continuous or substantially continuous barrier. For instance, the isolation structure 302 may extend from the opposing surface 218 of the silicon layer 216 downward into the silicon layer 216 to a depth sufficient to provide electrical isolation from the avalanche layers 206. By way of another example, the isolation structure 302 may surround three or more sides of the non-avalanche region 224. However, note that this is a nonlimiting example and that the isolation structure 302 may include any suitable shape, size, placement, and configuration for at least partially electrically isolating the non-avalanche region 224.

Due to the isolation structure 302, the non-avalanche region 224 may be isolated from electrical influence and noise generated by avalanche gain and multiplication, negative biasing, and pixel operations (e.g., charge movements). The deep n-well bias node 310 (e.g., surface N+ contact) for the isolation structure 302 may also serve as a source and/or drain of the plurality of transfer gates 210 or a last gate of the array of pixels 202.

The isolation structure 302 may include any suitable shape. For example, a shape of the isolation structure 302 may include a walled vessel, concave vessel, tub, bowl, housing, and/or the like.

In embodiments, the isolation structure 302 includes a series of electrically connected layers 304, 306, 308 including at least one n-type layer.

The series of electrically connected layers 304, 306, 308 may be arranged in a stack and may include an N+ region 308, an n-well 306, and a deep n-well 304 extending from the opposing surface 218 of the silicon layer 216 to a depth. For example, the depth may be between 0.5 micron (µm) and 20µm (e.g., 10µm).

In embodiments, the isolation structure 302 is configured to be biased relative to a reference voltage. For purposes of the present disclosure, unless stated otherwise, being biased relative to a reference voltage includes being biased by a difference value relative to the reference voltage. For example, being “configured to be biased” may include being configured to receive an externally accessible electrical connection that a reference voltage may be connected to. For instance, the difference value may be at least one of: zero volts (e.g., equal to the reference voltage); and/or a minimum and/or maximum positive voltage difference value relative to the reference voltage. The reference voltage may be any suitable voltage such as ground or any other voltage (e.g., a positive voltage). For example, the isolation structure 302 may be biased via a voltage VDNW applied to a deep n-well bias node 310. For example, the isolation structure 302 may be electrically connected to the deep n-well bias node 310 (e.g., electrical contact) configured to be biased at zero volts or at a positive voltage. For instance, the reference voltage and/or the difference value may be at least one of zero volts; or a positive voltage (e.g., less than 9 volts). For example, the reference voltage may be equal to a voltage of the silicon layer 216. By way of another example, the reference voltage may be equal to a voltage of a p-well 312 inside the isolation structure 302.

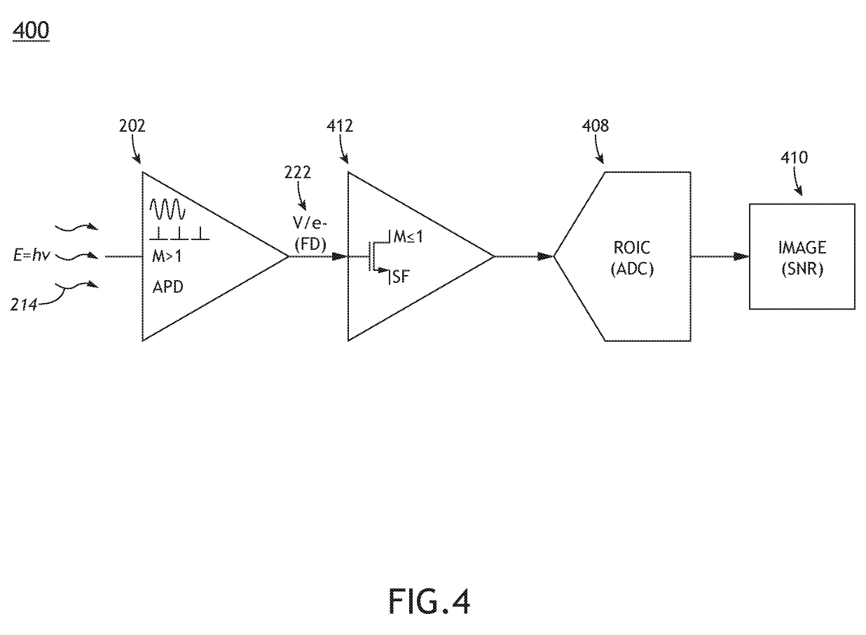

FIG. 4 illustrates a diagram 400 of a signal chain from radiation 214 to an image 410, in accordance with one or more embodiments of the present disclosure.

Portions of the image sensor 200 may be defined as an output circuit 412. Note that the output circuit 412 may be distinct from a read out integrated circuit (ROIC) 408. For example, the output circuit 412 may include elements such as the floating diffusion structure 222, a reset transistor, and the one or more amplifiers.

In embodiments, the image sensor 200 includes, in addition to the array of pixels 202 and the non-pixel region 204, a read out integrated circuit (ROIC) 408. The ROIC 408 may include an Analog-to-Digital Converter (ADC). The charge from the array of pixels 202 may be converted to voltage via a floating diffusion structure 222, and the voltage may be buffered by one or more amplifiers. In embodiments, one or more intermediary components (e.g., additional amplifiers) may be disposed before the ROIC 408. The ROIC 408 may convert the voltage signal to a digital number. For example, each sensing node of the image sensor 200 may include a respective floating diffusion structure 222. The non-pixel region 204 may include, or be defined as, a plurality of sensing nodes. For example, each sensing node may be coupled to one or more columns of pixels 202.

The ROIC 408 may be configured to convert a voltage output by each sensing node to a digital number. For example, the digital number may be indicative of an intensity/brightness of light received at the pixel 202 and may be combined with other digital numbers to form an image 410, which may be referred to as an image signal, image data, image sensor data, or the like. The image 410 may have a higher signal-to-noise ratio (SNR) than images made from image sensors 200 without a non-avalanche region 224 defined by an absence of avalanche layers 206.

The ROIC 408 may be integrated on a same substrate as the array of pixels 202 and the non-pixel region 204. In this case, the isolation structure 302 may be extended to also at least partially enclose the ROIC 408. For example, the isolation structure 302 may enclose the entire ROIC 408 or a select portion (e.g., set of components) of the ROIC 408.

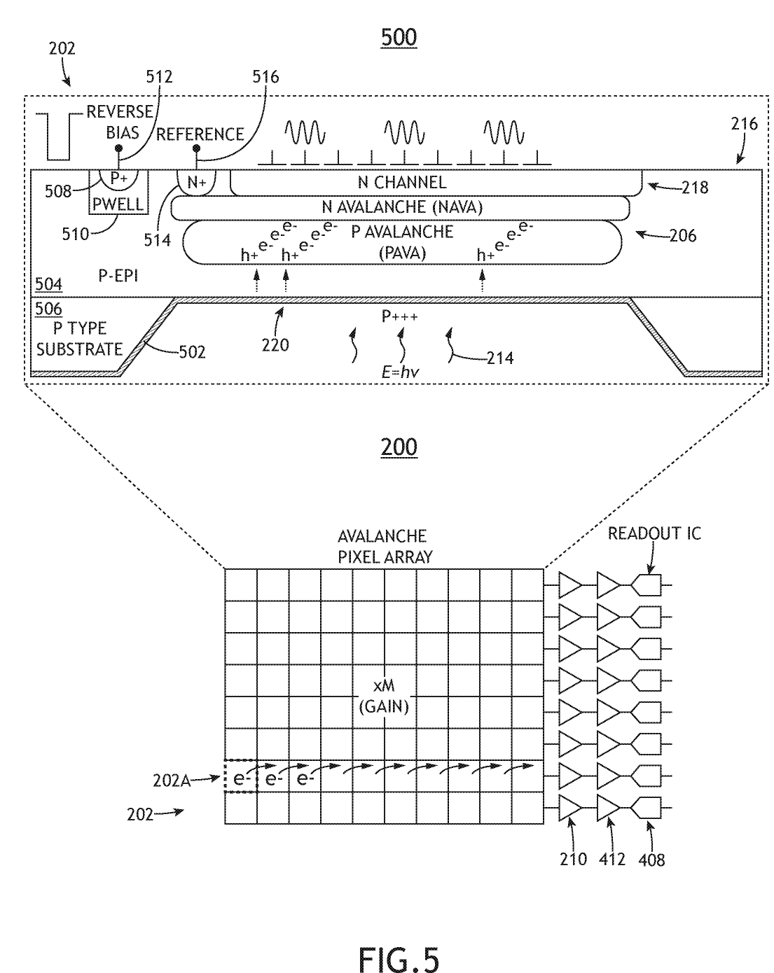

FIG. 5 illustrates a schematic diagram 500 depicting a side, cross-sectional view of a portion of an image sensor 200 on the top and a top plan view of an architectural diagram of the image sensor 200 on the bottom, in accordance with one or more embodiments of the present disclosure.

In embodiments, the silicon layer 216 may be coupled to a boron layer 502 disposed at the light-sensitive surface 220 of the silicon layer 216. The boron layer 502 may include a thin p+ dopant layer having a dopant concentration at least ten times higher than a dopant concentration of the silicon layer 216. The boron layer 502 may be formed by any suitable process. For example, the boron layer 502 may be formed by chemical vapor deposition (CVD), plasma chemical vapor deposition (PCVD), atomic layer deposition (ALD), ion implantation, or the like. An optional electrical connection (not shown) may be coupled to the boron layer 502 to apply a bias voltage (e.g., ground). In embodiments, the silicon layer 216 includes a p-type epitaxial layer 504 disposed on a p-type substrate 506. In embodiments, the silicon layer 216 further includes a p+ region 508 disposed within a p-well 510 at the opposing surface 218, where the p+ region 508 is electrically coupled to an anode contact 512 configured to receive an anode reverse-bias potential. In embodiments, the image sensor 200 further includes a cathode contact 516 electrically coupled to the nava layer of the avalanche layers 206 through a n+ portion 514. The cathode contact 516 may be biased to a reference potential (e.g., ground, or a positive voltage). In embodiments, the anode contact 512 and the cathode contact 516 are electrically coupled (directly or indirectly) to the avalanche layers 206--including the p-type doped layer 206B and the n-type doped layer 206A--such that a reverse bias is applied across the avalanche layers 206 during avalanche multiplication.

For illustrative purposes, a backside illuminated (BSI) image sensor is shown. During operation, radiation 214 (e.g., incident light) impinges on the light-sensitive surface 220 (e.g., back-side surface) where a relatively high-concentration of p-type dopants may be deposited. Then, photo-generated electrons may travel from the light-sensitive surface 220 toward the avalanche layers 206, where a strong electric field is formed by a reverse bias applied. Once electrons arrive at the avalanche layers 206, the electrons are accelerated and knock bound electrons out of atoms and generate additional electrons in an avalanche multiplication process. The multiplied electrons may be collected by pixel gates of each pixel 202A of the array of pixels 202 and shifted pixel-by-pixel through multiple rows of pixels 202 as indicated. Referring back to FIG. 2, the transferred and accumulated charges may be transferred by the transfer gates 210, converted to voltage signals and amplified by the output circuit 412, and then read out by a readout integrated circuit 408. Note that the readout integrated circuit 408 may be integrated on a same chip as the other components and/or may be on a separate chip.

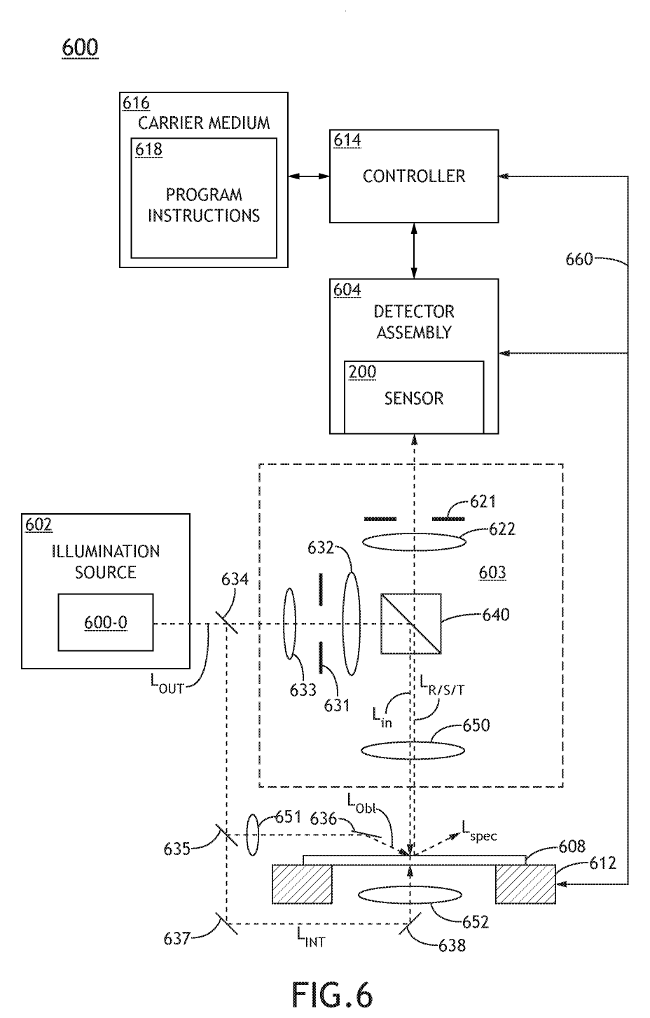

Although FIG. 6 illustrates the image sensor 200 in the context of an inspection system configuration, this is a nonlimiting example. The image sensor 200 may be incorporated into any suitable optical system or vision application. For example, the image sensor 200 may be incorporated into motion vision systems (e.g., TDI). For instance, the image sensor 200 may be incorporated into semiconductor manufacturing systems, semiconductor process monitoring systems. By way of another example, the image sensor 200 may be incorporated into machine vision systems, scientific imaging systems, or industrial imaging systems. However, note that this is a nonlimiting set of examples and that the image sensor 200 may be incorporated into any optical system or vision application suitable for utilizing the avalanche gain and non-avalanche region architecture described herein.

FIG. 6 illustrates a simplified block diagram of an optical system 600, in accordance with one or more embodiments of the present disclosure. FIG. 6 illustrates the incorporation of one or more image sensors of the present disclosure in optical system 600. The various optical elements and operating modes depicted in FIG. 6 are provided merely for illustrative purposes and should not be interpreted as a limitation on the scope of the present disclosure. Additional optical elements and sub-systems may be incorporated as needed for a specific application.

In embodiments, the optical system 600 is configured as an inspection system and/or a metrology system for inspecting a sample 608 and/or acquiring optical metrology measurements from the sample 608. The optical system 600 may be configured as a semiconductor fabrication system or be coupled to a semiconductor fabrication system to transmit measurements to the semiconductor fabrication system in a feedback loop to improve the manufacture of samples based on the measurements from the optical system 600. For example, the fabrication system may be configured to cut, drill or ablate material from sample 608, or to expose a pattern onto photoresist on sample 608.

When the sample 608 is illuminated in one or more of the above-described modes, the optics 603 are also configured to collect light L_{R/S/T} reflected, scattered, diffracted, transmitted and/or emitted from the sample 608 and direct and focus the light L_{R/S/T} to image sensor 200 of a detector assembly 604.

In embodiments, the image sensor 200 may include, but is not limited to, a charge-coupled device (CCD) detector, a complementary metal oxide semiconductor (CMOS) detector, a time-delay integration (TDI) detector, a line sensor, and/or the like. The detector assembly 604 may be communicatively coupled to a controller 614 (e.g., computing system). The image sensor 200 may be positioned in a path of light from the sample 608, to image the sample 608.

The controller 614 may be configured to store and/or analyze data from detector assembly 604 under control of program instructions 618 stored on carrier medium 616. The controller 614 may be further configured to control other elements of optical system 600 such as, but not limited to, stage 612, illumination source 602, and optics 603.

The sample 608 may include any sample known in the art such as, but not limited to, a wafer, reticle, photomask, or the like. In embodiments, the sample 608 may be disposed on a stage 612 to facilitate movement of the sample 608. The stage 612 may include any stage assembly known in the art including, but not limited to, an X-Y stage, an R-θ stage, and the like. In embodiments, the stage 612 is capable of adjusting the height of the sample 608 during inspection to maintain focus on the sample 608. In embodiments, a lens such as, but not limited to, objective lens 650 may be moved up and down during inspection to maintain focus on the sample 608.

In embodiments, the optical system 600 includes an illumination source 602 that incorporates a laser 600-0 that generates output light L_{OUT} having an output frequency ω_{OUT}. However, note that this is a nonlimiting example and that the illumination source 602 may include any type of illumination source suitable for providing the output light L_{OUT}. In embodiments, the illumination source 602 is a laser source. For example, the illumination source 602 may include, but is not limited to, one or more narrowband laser sources, a broadband laser source, a supercontinuum laser source, a white light laser source, or the like. In this regard, the illumination source 602 may provide an output light L_{OUT} having high coherence (e.g., high spatial coherence and/or temporal coherence). In embodiments, the illumination source 602 includes a laser-sustained plasma (LSP) source. For example, the illumination source 602 may include, but is not limited to, a LSP lamp, a LSP bulb, or a LSP chamber suitable for containing one or more elements that, when excited by a laser source into a plasma state, may emit broadband illumination.

In embodiments, the optical system 600 includes an optical sub-system configured to direct the illumination (e.g., light L_{OUT}) from the illumination source 602 onto the sample 608. Such an optical sub-system may be referred to as an illumination sub-system. For example, the optical sub-system may include any suitable elements known in the art for directing the illumination such as, but not limited to, elements 634, 633, 631, 632, 640, 650 and/or the like. As shown, the optical sub-system may include a beamsplitter 640. The optics 603 may include any number and type of illumination optic 633.

In embodiments, the optical system 600 includes one or more optical components such as, but not limited to, beam splitters, mirrors, lenses, apertures, and waveplates that are configured to condition and direct light L_{OUT} to sample 608. The optical components may be configured to illuminate an area, a line, or a spot on sample 608. In embodiments, beam splitter or mirror 634, mirrors 637 and 638, and lens 652 are configured to illuminate sample 608 from below so as to enable inspection or measurement of sample 608 by transmitting light L_{INT} through the sample. In embodiments, beam splitters or mirrors 634 and 635, mirror 636, and lens 651 are configured to illuminate sample 608 with light at an oblique angle of incidence L_{Obl}, for example at an angle of incidence greater than 60° relative to a normal to the sample surface. In this embodiment, the secularly reflected light L_{Spec} may be blocked or discarded rather than collected. In embodiments, optics 603 are collectively configured to direct illumination light L_{IN} to the top surface of sample 608.

In embodiments, the optics 603 includes one or more illumination tube lens 632. The illumination tube lens 632 may be configured to image an illumination pupil aperture 631 to a pupil within an objective lens 650. For example, the illumination tube lens 632 may be configured such that the illumination pupil aperture 631 and the pupil within the objective lens 650 are conjugate to one another. In embodiments, the illumination pupil aperture 631 may be configurable by switching different apertures into the location of illumination pupil aperture 631. In embodiments, the illumination pupil aperture 631 may be configurable by adjusting a diameter or shape of the opening of the illumination pupil aperture 631. In this regard, the sample 608 may be illuminated by different ranges of angles depending on the characterization (e.g., measurement or inspection) being performed under control of the controller 614. The illumination pupil aperture 631 may also include a polarizing element to control the polarization state of the illumination light L_{IN}.

In embodiments, the optics 603 includes a collection tube lens 622. For example, the collection tube lens 622 may be configured to image the pupil within the objective lens 650 to a collection pupil aperture 621. For instance, the collection tube lens 622 may be configured such that the collection pupil aperture 621 and the pupil within the objective lens 650 are conjugate to one another. In embodiments, the collection pupil aperture 621 may be configurable by switching different apertures into the location of collection pupil aperture 621. In embodiments, the collection pupil aperture 621 may be configurable by adjusting a diameter or shape of the opening of collection pupil aperture 621. In this regard, different ranges of angles of illumination reflected or scattered from the sample 608 may be directed to detector assembly 604 under control of the controller 614. The collection pupil aperture 621 may also include a polarizing element so that a specific polarization of light L_{R/S/T} can be selected for transmission to image sensor 200.

In embodiments, the illumination pupil aperture 631 and/or the collection pupil aperture 621 may include a programmable aperture.

The system 600 may include a controller 614 configured for inspecting or measuring the sample 608 based on output generated by the image sensor 200. For example, controller 614 shown in FIG. 6 may be configured in this manner. Controller 614 may be coupled to image sensor 200 in any suitable manner (e.g., via one or more transmission media, which may include "wired" and/or "wireless" transmission media) such that the controller 614 can receive the output, images, etc. generated by image sensor 200. Controller 614 may be configured to perform a number of functions using the output of the image sensor 200 as described herein and any other functions described further herein. This computing system may be further configured as described herein.

The controller 614 (e.g., computing system) may include one or more controllers (not shown) that are configured to perform one or more functions. For example, the one or more controllers may be configured to inspect or measure the sample based on the output of the image sensor 200. The controller(s) of the computing system (as well as other controllers described herein) may also be referred to herein as computer system(s). Each of the computing system(s) and controller(s) or system(s) described herein may take various forms, including a personal computer system, image computer, mainframe computer system, workstation, network appliance, Internet appliance, or other device. In general, the term "computer system" may be broadly defined to encompass any device having one or more processors, which executes instructions from a memory medium. The computing system(s) and controller(s) or system(s) may also include any suitable processor known in the art such as, but not limited to, a parallel processor. In addition, the computing system(s) and controller(s) or system(s) may include a computer platform with high-speed processing and software, either as a standalone or a networked tool.

If the system 600 includes more than one controller, then the different controllers may be coupled to each other such that images, data, information, instructions, etc. can be sent between the controllers as described further herein. For example, two or more controllers may be coupled to each other by any suitable transmission media (not shown), which may include any suitable wired and/or wireless transmission media known in the art. Two or more of such controllers may also be effectively coupled by a shared computer-readable storage medium (not shown).

The system 600 may further include connection 660 between controller 614 and detector assembly 604 and stage 612. Controller 614 may be configured to control the operation of detector assembly 604 and stage 612, and to receive relevant monitoring and/or diagnostic information from them. For example, controller 614 may generate and monitor signals necessary to bias or drive detector assembly 604 and signals necessary to ensure the synchronization between the movement of stage 612 and the image collection by detector assembly 604. For example, the signals necessary to bias or drive detector assembly 604 may include power supply voltages or timings and voltages of driving clocks. Connection 660 may include any suitable wired and/or wireless transmission media known in the art.

The system 600 illustrated in FIG. 6 is an example for illustrative purposes only and is not meant to be limiting. Various configurations described herein may be altered to adjust the performance of the system 600 as is commonly performed by persons of the art when designing a commercial system. In addition, the systems described herein may be implemented using an existing system (e.g., by adding the image sensor embodiments and other functionality described herein to an existing system) such as systems that are commercially available from KLA Corp., Milpitas, California. For some such systems, the embodiments described herein may be provided as optional functionality of the existing system (e.g., in addition to other functionality of the system). Alternatively, the system described herein may be designed "from scratch" to provide a completely new system.

The controller 614 may be configured for inspecting or measuring a sample in a number of different ways depending on, for example, the sample, the optical system configuration, and information being determined for the sample. For example, in embodiments, the system may be configured as an inspection system, and the information for the sample includes information for defects detected on the sample based on the output. In one such example, controller 614 may be configured for detecting defects on sample 608 by applying a defect detection method to the output generated by image sensor 200. Controller 614 may be coupled to image sensor 200 as described further herein so that it can receive the output generated by the sensor. Detecting defects on the sample may be performed in any suitable manner known in the art (e.g., applying a defect detection threshold to the output and determining that any output having a value above the threshold corresponds to a defect or a potential defect) with any suitable defect detection method and/or algorithm.

In another embodiment, the system is configured as a metrology system. In a further embodiment, the system is configured as a defect review system. For example, the embodiment of the system shown in FIG. 6 may be modified in one or more parameters to provide different imaging capability depending on the application for which it will be used. In one such example, the system may be configured to have a higher resolution if it is to be used for metrology rather than for inspection. In other words, the embodiment of the system shown in FIG. 6 describes some general and various configurations for a system that can be tailored in a number of manners that will be obvious to one skilled in the art to produce systems having different imaging capabilities that are more or less suitable for different applications.

In this manner, the system may be configured for generating output that is suitable for re-detecting defects on the sample in the case of a defect review system and for measuring one or more characteristics of the sample in the case of a metrology system. In a defect review system embodiment, controller 614 may be configured for re-detecting defects on sample 608 by applying a defect re-detection method to the output generated by image sensor 200 and possibly determining additional information for the re-detected defects using the output generated by the sensor. In a metrology system embodiment, controller 614 may be configured for determining one or more characteristics of sample 608 using the output generated by the sensor.

Defect review typically involves re-detecting defects detected as such by an inspection process and generating additional information about the defects at a higher resolution, e.g., using the system described herein in a high magnification mode. Defect review is therefore performed at discrete locations on the sample where defects have been detected by inspection. The higher resolution data for the defects generated by defect review is generally more suitable for determining attributes of the defects. For example, defect attributes may include profile, roughness, more accurate size information, and the like. Controller 614 may be configured to determine such information for defects on the sample in any suitable manner known in the art.

Metrology processes are used at various steps during a semiconductor manufacturing process to monitor and control the process. Metrology processes are different than inspection processes in that, unlike inspection processes in which defects are detected on a sample, metrology processes are used to measure one or more characteristics of the sample that cannot be determined using currently used inspection tools. For example, metrology processes are used to measure one or more characteristics of a sample. For instance, characteristics of the sample may include a dimension (e.g., line width, thickness, etc.) of features formed on the sample during a process such that the performance of the process can be determined from the one or more characteristics. In addition, if the one or more characteristics of the sample are unacceptable (e.g., out of a predetermined range for the characteristic(s)), the measurements of the one or more characteristics of the sample may be used to alter one or more parameters of the process such that additional samples manufactured by the process have acceptable characteristic(s).

Metrology processes are also different than defect review processes in that, unlike defect review processes in which defects that are detected by inspection are re-visited in defect review, metrology processes may be performed at locations at which no defect has been detected. In other words, unlike defect review, the locations at which a metrology process is performed on a sample may be independent of the results of an inspection process performed on the sample. In particular, the locations at which a metrology process is performed may be selected independently of inspection results. In addition, since locations on the sample at which metrology is performed may be selected independently of inspection results, unlike defect review in which the locations on the sample at which defect review is to be performed cannot be determined until the inspection results for the sample are generated and available for use, the locations at which the metrology process is performed may be determined before an inspection process has been performed on the sample. Controller 614 may be configured to determine any suitable characteristics for the sample in any suitable manner known in the art.

In any of the system embodiments described herein, controller 614 shown in FIG. 6 may be configured to generate results that include at least the information determined for the sample 608 based on the output generated by the image sensor 200 possibly with any other output generated by the controller 614. The results may have any suitable format (e.g., a KLARF file, which is a proprietary file format used by tools commercially available from KLA, a results file generated by Klarity, which is a tool that is commercially available from KLA, a lot result, etc.). In addition, all of the embodiments described herein may be configured for storing results of one or more steps of the embodiments in a computer-readable storage medium (e.g., non-transitory medium such as, but not limited to, a hard-drive or the like). The results may include any of the results described herein and may be stored in any manner known in the art. The storage medium may include any storage medium described herein or any other suitable storage medium known in the art. After the results have been stored, the results can be accessed in the storage medium and used by any of the method or system embodiments described herein, formatted for display to a user, used by another software module, method, or system, etc. to perform one or more functions for the sample or another sample.

Such functions include, but are not limited to, altering a process. For example, a process that may be altered may include a fabrication process or step that was or will be performed on the sample in a feedback, feedforward, in-situ manner, or the like. For example, the controller may be configured to determine one or more changes to a process that was or will be performed on the sample based on the detected defect(s) and/or other determined information. The changes to the process may include any suitable changes to one or more parameters of the process. For example, if the determined information is defects detected on the sample, the controller may determine those changes such that the defects may be reduced or prevented on other samples on which the revised process is performed, the defects can be corrected or eliminated on the sample in another process performed on the sample, the defects can be compensated for in another process performed on the sample, etc. The controller may determine such changes in any suitable manner known in the art.

Those changes can then be sent to a semiconductor fabrication system (not shown) or a storage medium (not shown in FIG. 6) accessible to both the controller and the semiconductor fabrication system. The semiconductor fabrication system may or may not be part of the system embodiments described herein. For example, the systems described herein may be coupled to the semiconductor fabrication system, e.g., via one or more common elements. For instance, the common elements may include a housing, a power supply, a sample handling device or mechanism, or the like. The semiconductor fabrication system may include any semiconductor fabrication system known in the art. For example, the semiconductor fabrication system may include a lithography tool, an etch tool, a chemical-mechanical polishing (CMP) tool, a deposition tool, and the like.

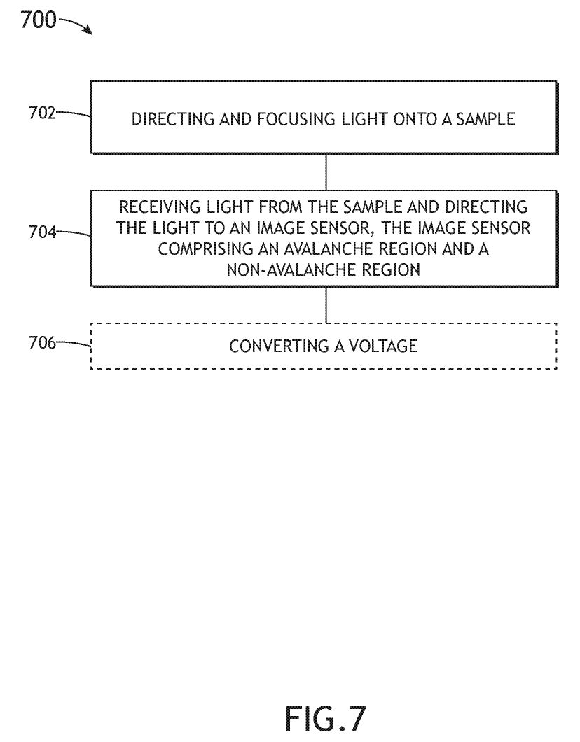

FIG. 7 illustrates a flow diagram depicting a method 700 for inspecting a sample 608, in accordance with one or more embodiments of the present disclosure. It is noted that the embodiments and enabling technologies described previously herein in the context of the system 600 and the image sensor 200 should be interpreted to extend to the method 700. It is further noted herein that the steps of method 700 may be implemented all or in part by system 600 and the image sensor 200. It is further recognized, however, that the method 700 is not limited to the system 600 and the image sensor 200 in that additional or alternative system-level embodiments may carry out all or part of the steps of method 700.

At step 702, light may be directed and focused onto the sample 608. For example, the illumination source 602 may be used to generate the light (e.g., L_{OUT}) and the light may be directed to the sample 608 using the illumination sub-system of the system 600.

At step 704, light from the sample 608 may be received and directed to the image sensor 200. For example, the image sensor 200 may be equivalent to the image sensor 200 of FIGS. 2 and/or 3. The image sensor 200 may include an avalanche region 208 defined by one or more avalanche layers 206 and a non-avalanche region 224 defined by an absence of avalanche layers 206.

At step 706, a readout circuit may be utilized to convert a voltage output by each sensing node to a digital number. For example, the readout circuit may include the readout integrated circuit (ROIC) 408 of FIG. 4, and may be adjacent to or located away from the plurality of circuits of the image sensor 200. The readout circuit may include an Analog-to-Digital Converter (ADC) coupled to an output circuit, such as, but not limited to, output circuit 412 of FIG. 4. Note that being “coupled to” may mean, unless otherwise noted, that there are one or more intermediary elements, such as one or more additional amplifiers or any other components.

With respect to the use of substantially any plural and/or singular terms herein, those having skill in the art can translate from the plural to the singular and/or from the singular to the plural as is appropriate to the context and/or application. The various singular/plural permutations are not expressly set forth herein for the sake of clarity.

The description is presented to enable one of ordinary skill in the art to make and use the disclosure as provided in the context of a particular application and its requirements. As used herein, directional terms such as "top," "bottom," "over," "under," "upper," "upward," "lower," "down," and "downward" are intended to provide relative positions for purposes of description and are not intended to designate an absolute frame of reference. Various modifications to the preferred embodiment will be apparent to those with skill in the art, and the general principles defined herein may be applied to other embodiments. Therefore, the present disclosure is not intended to be limited to the particular embodiments shown and described but is to be accorded the widest scope consistent with the principles and novel features herein disclosed.

Furthermore, it is to be understood that the invention is defined by the appended claims. It will be understood by those within the art that, in general, terms used herein, and especially in the appended claims (e.g., bodies of the appended claims) are generally intended as "open" terms (e.g., the term "including" should be interpreted as "including but not limited to," the term "having" should be interpreted as "having at least," the term "includes" should be interpreted as "includes but is not limited to," and the like). It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases "at least one" and "one or more" to introduce claim recitations. However, the use of such phrases should not be construed to imply that the introduction of a claim recitation by the indefinite articles "a" or "an" limits any particular claim containing such introduced claim recitation to inventions containing only one such recitation, even when the same claim includes the introductory phrases "one or more" or "at least one" and indefinite articles such as "a" or "an" (e.g., "a" and/or "an" should typically be interpreted to mean "at least one" or "one or more"); the same holds true for the use of definite articles used to introduce claim recitations. In addition, even if a specific number of an introduced claim recitation is explicitly recited, those skilled in the art will recognize that such recitation should typically be interpreted to mean at least the recited number (e.g., the bare recitation of "two recitations," without other modifiers, typically means at least two recitations, or two or more recitations). Furthermore, in those instances where a convention analogous to "at least one of A, B, and C, and the like" is used, in general such a construction is intended in the sense one having skill in the art would understand the convention (e.g., "a system having at least one of A, B, and C" would include but not be limited to systems that have A alone, B alone, C alone, A and B together, A and C together, B and C together, and/or A, B, and C together, and the like). In those instances where a convention analogous to "at least one of A, B, or C, and the like" is used, in general such a construction is intended in the sense one having skill in the art would understand the convention (e.g., "a system having at least one of A, B, or C" would include but not be limited to systems that have A alone, B alone, C alone, A and B together, A and C together, B and C together, and/or A, B, and C together, and the like). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase "A or B" will be understood to include the possibilities of "A" or "B" or "A and B."

It is believed that the present disclosure and many of its attendant advantages will be understood by the foregoing description, and it will be apparent that various changes may be made in the form, construction and arrangement of the components without departing from the disclosed subject matter or without sacrificing all of its material advantages. The form described is merely explanatory, and it is the intention of the following claims to encompass and include such changes. Furthermore, it is to be understood that the invention is defined by the appended claims.

We claim:

1. An image sensor comprising:
a silicon layer comprising a light-sensitive surface and an opposing surface on an opposite side from the light-sensitive surface;
a plurality of circuits formed on the opposing surface of the silicon layer, wherein the plurality of circuits collectively comprise:
an array of pixels configured to be photosensitive; and
a non-pixel region comprising a plurality of transfer gates and one or more amplifiers;
an avalanche region defined by one or more avalanche layers; and
a non-avalanche region defined by an absence of avalanche layers;
wherein the avalanche region is selectively disposed overlapping in a first direction with the array of pixels, wherein the non-avalanche region is defined overlapping in the first direction with at least a portion of the non-pixel region.

2. The image sensor of claim 1, wherein the non-avalanche region is defined overlapping in the first direction with both the plurality of transfer gates and the one or more amplifiers.

3. The image sensor of claim 1, wherein the non-avalanche region is defined overlapping in the first direction with an entirety of both the plurality of transfer gates and the one or more amplifiers.

4. The image sensor of claim 1, wherein the avalanche region comprises at least:
a p-type doped layer; and
an n-type doped layer.

5. The image sensor of claim 1, wherein the array of pixels is arranged in a two-dimensional array to detect radiation.

6. The image sensor of claim 1, wherein the non-pixel region is disposed adjacent to the array of pixels, wherein the plurality of transfer gates is configured to transfer charge from the array of pixels.

7. The image sensor of claim 1, wherein the non-pixel region further comprises a floating diffusion structure configured to convert charge to voltage.

8. The image sensor of claim 1, wherein the silicon layer comprises a silicon epitaxial layer.

9. The image sensor of claim 1, wherein the image sensor is configured as a backside illuminated charge-coupled device (CCD) sensor.

10. The image sensor of claim 1, wherein the image sensor is configured as a backside illuminated complementary metal-oxide-semiconductor (CMOS) sensor.

11. The image sensor of claim 1, wherein the image sensor is configured to function as a time-delay integration (TDI) sensor.

12. The image sensor of claim 1, further comprising an isolation structure at least partially enclosing the non-avalanche region, and configured to at least partially electrically isolate the non-avalanche region.

13. The image sensor of claim 12, wherein the isolation structure is configured to be biased to a reference voltage, wherein being biased to the reference voltage includes being biased by a difference value relative to the reference voltage.

14. The image sensor of claim 12, wherein the isolation structure comprises a series of electrically connected layers, comprising at least one n-type layer.

15. The image sensor of claim 14, wherein the series of electrically connected layers are arranged in a stack and comprise an N+ region, an n-well, and a deep n-well extending from the opposing surface of the silicon layer.

16. A system configured for inspecting or measuring a sample, comprising:
an illumination sub-system configured for directing light generated by an illumination source to the sample;
an image sensor positioned in a path of light from the sample and comprising:
a silicon layer comprising a light-sensitive surface and an opposing surface on an opposite side from the light-sensitive surface;
a plurality of circuits formed on the opposing surface of the silicon layer, wherein the plurality of circuits collectively comprise:
an array of pixels; and
a non-pixel region comprising a plurality of transfer gates and one or more amplifiers;
an avalanche region defined by one or more avalanche layers; and
a non-avalanche region defined by an absence of avalanche layers;
wherein the avalanche region is selectively disposed overlapping in a first direction with the array of pixels, wherein the non-avalanche region is defined overlapping in the first direction with at least a portion of the non-pixel region; and
a controller configured to receive output generated by the image sensor.

17. The system of claim 16, wherein the system is configured as at least one of an inspection system or a metrology system.

18. A method for inspecting or measuring a sample, the method comprising:
directing and focusing light onto the sample; and
collecting light from the sample and directing the collected light to an image sensor, the image sensor comprising:
a silicon layer comprising a light-sensitive surface and an opposing surface on an opposite side from the light-sensitive surface;
a plurality of circuits formed on the opposing surface of the silicon layer, wherein the plurality of circuits collectively comprise:
an array of pixels; and
a non-pixel region comprising a plurality of transfer gates and one or more amplifiers;
an avalanche region defined by one or more avalanche layers; and
a non-avalanche region defined by an absence of avalanche layers;
wherein the avalanche region is selectively disposed overlapping in a first direction with the array of pixels, wherein the non-avalanche region is defined overlapping in the first direction with at least a portion of the non-pixel region.

19. The method of claim 18, further comprising:
converting a voltage output by each sensing node of the image sensor to a digital number.

20. The method of claim 18, wherein the non-avalanche region is defined overlapping in the first direction with both the plurality of transfer gates and the one or more amplifiers.
